(19) United States
(12) Patent Application Publication
(10) Pub. No.: US 2014/0376071 A1
(43) Pub. Date: Dec. 25, 2014

(54) Micromechanical component, micromirror device, and manufacturing method for a micromechanical component

(71) Applicants: Simon ARMBRUSTER, Wannweil (DE); Helmut GRUTZECK, Kusterdingen (DE); Joerg MUCHOW, Reutlingen (DE); Frederic Njikam NJIMONZIE, Reutlingen (DE); Johannes BAADER, Wannweil (DE); Stefan PINTER, Reutlingen (DE); Rainer STRAUB, Ammerbuch (DE); Zoltan LESTYAN, Martonvasar (HU)

(72) Inventors: Simon ARMBRUSTER, Wannweil (DE); Helmut GRUTZECK, Kusterdingen (DE); Joerg MUCHOW, Reutlingen (DE); Frederic Njikam NJIMONZIE, Reutlingen (DE); Johannes BAADER, Wannweil (DE); Stefan PINTER, Reutlingen (DE); Rainer STRAUB, Ammerbuch (DE); Zoltan LESTYAN, Martonvasar (HU)

(73) Assignee: Robert Bosch GmbH, Stuttgart (DE)

(21) Appl. No.: 14/314,192

(22) Filed: Jun. 25, 2014

(30) Foreign Application Priority Data
Jun. 25, 2013 (DE) 10 2013 212 102.4

(51) Int. Cl. G02B 26/08; B81C 1/00

(52) U.S. Cl. CPC G02B 26/0833; B81C 1/0019
USPC 359/221.2; 29/446

(57) ABSTRACT

A micromechanical component includes a mounting, and a mirror plate which is adjustable with respect to the mounting about at least one rotational axis and which has a mirror side and a rear side which faces away from the mirror side. The mirror plate is connected to the mounting at least via four springs. Each of the four springs extends partially along the rear side of the mirror plate and is connected to the mirror plate via one support post each, which in each case contacts an anchoring area situated on the rear side. Also described is a micromirror device, as well as a manufacturing method for a micromechanical component.

### RELATED APPLICATION INFORMATION

The present application claims priority to and the benefit of German patent application no. 10 2013 212 102.4, which was filed in Germany on Jun. 25, 2013, the disclosure of which is incorporated herein by reference.

### FIELD OF THE INVENTION

The present invention relates to a micromechanical component and a micromirror device. Moreover, the present invention relates to a manufacturing method for a micromechanical component.

### BACKGROUND INFORMATION

A micromirror device is discussed in U.S. Pat. No. 7,567,367 B2. In one specific embodiment the micromirror device has a mirror plate which is adjustable about two rotational axes, the mirror plate being connected to a mounting via two outer springs and two inner springs. The outer springs extend between the mounting and an outer frame. The inner springs are situated between the outer frame and an inner frame. The inner frame is connected to the mirror plate with the aid of four connecting elements. The four connecting elements have anchoring areas at a side edge of the mirror plate, a first rotational axis of the two rotational axes intersecting two anchoring areas, and a second rotational axis of the two rotational axes extending through the two other anchoring areas.

### SUMMARY OF THE INVENTION

The present invention provides a micromechanical component having the features of Claim 1, a micromirror device having the features of Claim 13, and a manufacturing method for a micromechanical component having the features of Claim 15.

With the aid of the connection according to the present invention of the mirror plate to the mounting via the four springs, each of which has a support post which contacts the rear side of the mirror plate, (dynamic) deformation of the mirror side of the mirror plate which occurs during an adjustment of the mirror plate about the at least one rotational axis may be prevented/minimized. Thus, in the subject matter of the present invention, the mirror side of the mirror plate is reliably protected from deformation during the adjustment of the mirror plate about the at least one rotational axis. For a light beam which is deflected with the aid of the mirror side of the mirror plate, undesirable diffractions of the light beam occur less often. The present invention is therefore particularly suitable for implementing micromechanical components, with the aid of which light beams are deflectable, without an undesirable expansion of a light spot occurring.

In one advantageous specific embodiment of the micromechanical component, each of the four anchoring areas of the four support posts is situated at a distance from the at least one rotational axis, about a vector having a component which is oriented in parallel to the mirror side. In other words, each of the four springs contacts the rear side of the mirror plate at one point in each case which does not coincide with the at least one rotational axis. Such a connection of the four support posts to the rear side of the mirror plate contributes to an additional reduction in the (dynamic) deformation of the mirror side of the mirror plate during the adjustment of the mirror plate about the at least one rotational axis.

Although the present invention is described with reference to four springs, each having one anchoring area, more than the four springs may also be used for implementing the present invention. In addition, each of the at least four springs may also be configured with multiple anchoring areas.

The four anchoring areas may be situated on the rear side, axially symmetrically with respect to the at least one rotational axis. This results in a more uniform distribution of the forces exerted on the rear side of the mirror plate with the aid of the springs, and thus, less deformation of the mirror side of the mirror plate during adjustment of same.

For example, the four anchoring areas may be situated on the rear side, axially symmetrically with respect to the single rotational axis and a mirror axis of symmetry which is oriented orthogonally with respect to the single rotational axis, or axially symmetrically with respect to the two rotational axes. A uniform distribution of the forces exerted on the rear side of the mirror plate with the aid of the springs is ensured in both cases.

Each of the four anchoring areas of the four support posts may be situated at a distance from a lateral edge of the rear side. The distance between the anchoring areas and the lateral edge of the rear side may be, for example, at least 5% of an extension of the mirror plate, i.e., 0.1 mm for an extension of at least 2 mm. Due to the anchoring of the four support posts at a distance from the lateral edge of the rear side, a mirror suspension is achievable which contributes to minimizing the deformation of the mirror side of the mirror plate which is induced by the four springs.

For example, the mirror plate may have an extension of at least 2 mm, a system which is formed from the mirror plate and the four springs having a natural frequency of at least 18 kHz. In particular, the system may have a natural frequency of at least 20 kHz, 22 kHz, 25 kHz, or 30 kHz. As explained in greater detail below, the mirror plate may have a comparatively large/large surface area configuration without impairing its advantageous adjustability about the at least one rotational axis, (practically) free of (dynamic) deformations of the mirror side of the mirror plate.

In addition, the four springs may have a spiral-shaped, meander-shaped, and/or loop-shaped configuration, at least in sections. The four springs may thus be comparatively long without an associated undesirable increase in the space requirements of the micromechanical component.

In one advantageous specific embodiment, braces which extend from a central bulge of the mirror plate to an edge area of the rear side are formed on the rear side of the mirror plate. Even a mirror plate having a relatively small minimum thickness d may thus have a slight dynamic deformation.

Some of the braces may be inclined by an angle of inclination between 30° and 60° with respect to the at least one rotational axis, and have a first width, oriented perpendicularly with respect to the mirror side, which is larger than a second width of the other braces which is oriented perpendicularly with respect to the mirror side. Deformations of corners and/or of edge areas of the mirror plate situated at a distance from the at least one rotational axis may be prevented with the aid of such a configuration of the rear side of the mirror plate.

Alternatively or additionally, a ring which surrounds the central bulge, and whose radius is smaller than a length of the braces extending away from the central bulge, may be formed on the rear side. This type of ring, despite its small moment of inertia, improves the stability of the mirror plate.

In another advantageous specific embodiment, a central T bar which extends along the single rotational axis and which has a T-shaped cross section perpendicular to the single rotational axis is formed on the rear side of the mirror plate. The stability of the mirror plate may also be increased with the aid of this type of T bar.

In one advantageous refinement, the micromechanical component additionally includes a (second) micromirror which is adjustable in relation to the mounting about a rotational axis which is oriented perpendicularly with respect to the single rotational axis about which the mirror plate is adjustable relative to the mounting, the micromirror being situated in relation to the mirror plate in such a way that a light beam which is deflected on the micromirror is deflectable onto the mirror side of the mirror plate. Thus, a dual micromirror system may also be advantageously refined with the aid of the present invention.

The advantages listed above are also achieved with a micromirror device having such a micromechanical component.

The micromirror device may in particular be configured as an image projector and/or film projector. Since with the aid of the present invention a light beam is projectable onto a projection surface without resulting in an undesirable expansion of the light spot, good quality of an image or film which is projected with the aid of the micromirror device is ensured.

Furthermore, the advantages are achievable by carrying out the corresponding manufacturing method for a micromechanical component. The manufacturing method may be refined corresponding to the specific embodiments described above.

Further features and advantages of the present invention are explained below with reference to the figures.

### BRIEF DESCRIPTION OF THE DRAWINGS

FIGS. 1a, 1b, 1c, 1d, and 1e show schematic illustrations of a first specific embodiment of the micromechanical component and a computed dynamic mirror deformation (FEM simulation).

FIG. 2 shows a schematic illustration of a second specific embodiment of the micromechanical component.

FIG. 3 shows a schematic illustration of a third specific embodiment of the micromechanical component.

FIG. 4 shows a schematic illustration of a fourth specific embodiment of the micromechanical component.

FIGS. 5a and 5b show schematic illustrations of a fifth specific embodiment of the micromechanical component, FIG. 5b illustrating a cross section along line BB′ in FIG. 5a.

FIGS. 6a and 6b show schematic illustrations of a sixth specific embodiment of the micromechanical component, FIG. 6b illustrating a cross section along line CC′ in FIG. 6a.

FIG. 7 shows a schematic illustration of a seventh specific embodiment of the micromechanical component.

FIG. 8 shows a flow chart for explaining one specific embodiment of the manufacturing method for a micromechanical component.

### DETAILED DESCRIPTION

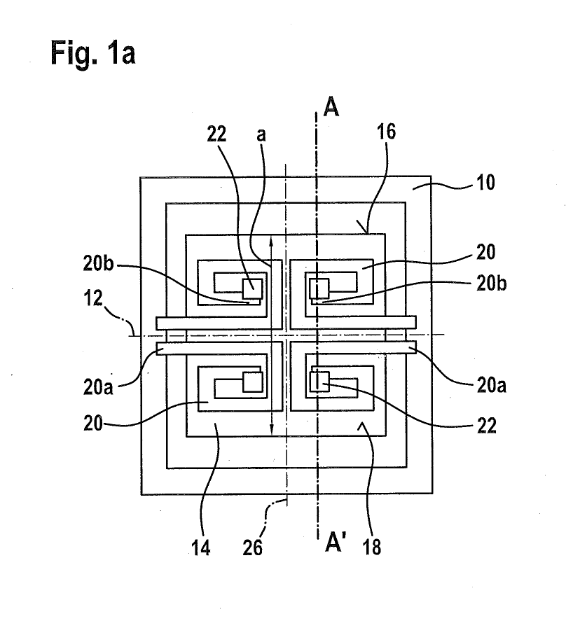

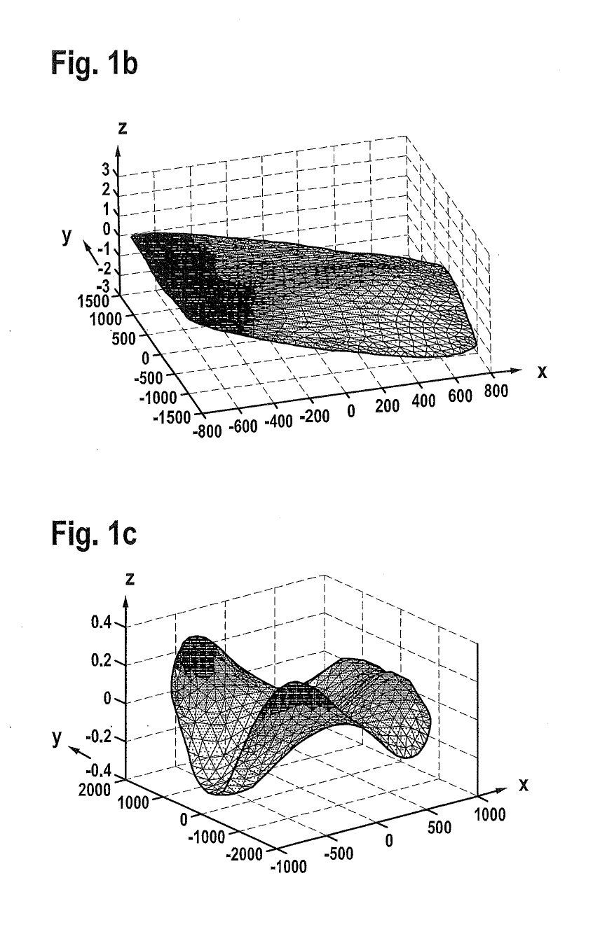

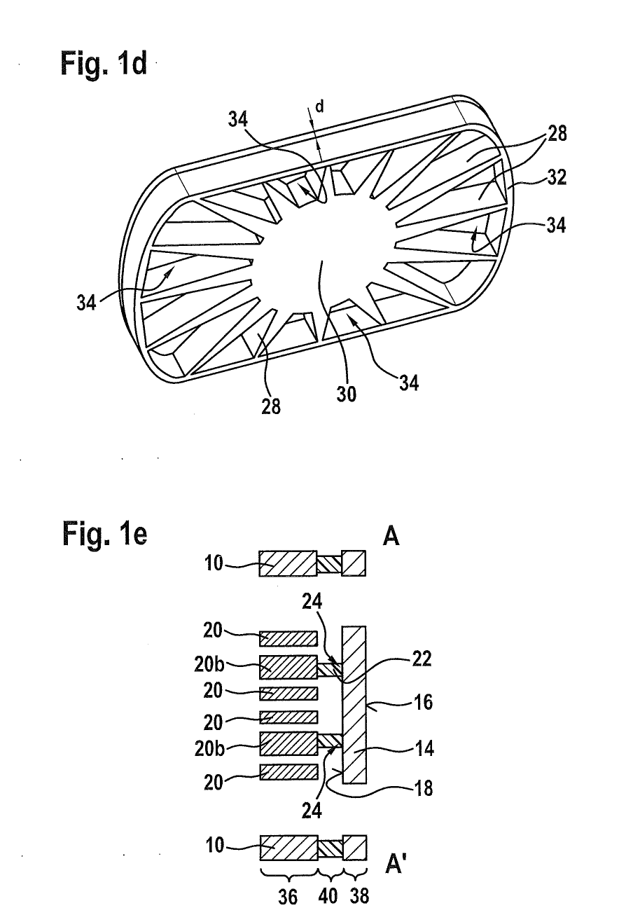

FIGS. 1a through 1e show schematic illustrations of a first specific embodiment of the micromechanical component and a computed dynamic mirror deformation (FEM simulation).

The micromechanical component schematically illustrated in a rear side view in FIG. 1a has a mounting 10 and a mirror plate 14 which is adjustable with respect to mounting 10 about at least one rotational axis 12. In the illustrated specific embodiment, mirror plate 14 is adjustable with respect to mounting 10 only about single rotational axis 12. As an alternative, however, mirror plate 14 may also be adjustable about two rotational axes which may be oriented perpendicularly with respect to one another. Mirror plate 14 has a mirror side 16 and a rear side 18 which faces away from mirror side 16. Mirror side 16 may be formed, for example, with the aid of (partial) polishing and/or a reflective (partial) coating of mirror plate 14.

Mirror plate 14 is connected to mounting 10 via at least four springs 20. Each of the four springs 20 extends partially along rear side 18 of mirror plate 14. In addition, each of the four springs 20 is connected to mirror plate 14 via one support post 22 each. Each of support posts 22 contacts an anchoring area 24 of mirror plate 14 situated on rear side 18.

Due to the advantageous connection of the four springs 20 to rear side 18 of mirror plate 14 via the four support posts 22, (dynamic) deformations which occur in particular at mirror side 16 of mirror plate 14 during a (which may be high-frequency) adjustment of mirror plate 14 about the at least one rotational axis 12 may be reduced/avoided. The use of the four springs 20 and the four support posts 22 also results in four contact points via which a mechanical stress is exertable by the four springs on mirror plate 14. The dynamic deformation of mirror plate 14 is based on the inherent inertia of mirror plate 14 and the spring contact forces. As a result of springs 20 contacting mirror plate 14 at multiple points, the overall mechanical system may be optimized in such a way that the spring contact forces and the forces caused by the inherent inertia of mirror plate 14 cancel each other out. A comparatively slight (dynamic) deformation of mirror side 16 during the adjustment of mirror plate 14 about the at least one rotational axis 12 may be ensured in this way.

Undesirable diffraction effects in a light beam which is reflected on mirror side 16 during the adjustment of mirror plate 14 about the at least one rotational axis 12 may be prevented/minimized with the aid of a reduction in the (dynamic) deformation of mirror side 16 which is thus ensured. In particular, an undesirable expansion of the light beam which is reflected on mirror side 16 is (virtually) prevented.

Support posts 22 may extend between a first plane of the four springs 20 and a second plane of mirror plate 14. In other words, support posts 22 extend perpendicularly with respect to mirror side 16, from springs 20 to mirror plate 14.

In the micromechanical component in FIG. 1a, at a first spring end 20a each of the four springs 20 is connected to mounting 10, in particular to a frame part of mounting 10. One alternative to an individual connection of the four springs 20 to mounting 10 is described in greater detail below. One support post 22 is connected/formed on each second spring end 20b of the four springs 20.

In the specific embodiment in FIGS. 1a through 1e, the four springs 20 have a spiral-shaped configuration, at least in sections. This may be understood to mean that each of the four springs 20 has a rolled-up shape, so that a second spring end 20b is at least partially surrounded by a spring section of the same spring 20. Such a configuration of the four springs 20 is associated with the advantage that the springs may be comparatively long without an extension of the micromechanical component, and thus its space requirements, being (significantly) increased. Springs 20 may also have a comparatively stiff configuration without the mechanical stress, which occurs therein, assuming values which would result in a concern for damage/rupture of springs 20.

FIGS. 1b and 1c show a computed dynamic mirror deformation (FEM simulation) which is caused by a high-frequency movement of mirror plate 14 (FIG. 1c shows an enlargement of FIG. 1b).

As is apparent with reference to the simulation, a deformation over the entire mirror side 16 may be reduced to approximately 0.2 μm. Within a laser spot (generally having a pressure gauge (diameter) of 1 mm), the deformation is thus less than 0.1 μm. It is thus ensurable that even during an adjustment of mirror plate 14 about single rotational axis 12 using high frequencies, a (dynamic) deformation which occurs at mirror side 16 approaches an ideal default of a mirror deformation having a maximum value of one-tenth of a wavelength of the light reflected with the aid of mirror side 16. In particular, an undesirable expansion of a light beam which is reflected with the aid of mirror side 16 is thus preventable.

In the micromechanical component schematically illustrated in FIG. 1a, each of the four anchoring areas 24 of the four support posts 22 is situated at a distance from a lateral edge of rear side 18. A minimum distance between each of the four anchoring areas 24 and the lateral edge of rear side 18 may be at least 5% of an extension a of rear side 18/mirror plate 14. In particular, the minimum distance between each of the four anchoring areas 24 and the lateral edge of rear side 18 may be at least 10% of extension a. The minimum distance of the four anchoring areas 24 from the lateral edge of rear side 18 may be at least 20% of extension a. (Extension a may be understood to mean a maximum length/width of mirror plate 14.)

A deformation of mirror plate 14 which is induced by the four springs 20 is minimizable in this way. Forces resulting from the inherent inertia of mirror plate 14 may be at least partially compensated for by a targeted increase in a mechanical stress which is exerted on mirror plate 14 with the aid of the four contacting springs 20. In addition, the implementation of four suspension points at the four anchoring areas 24 ensures that a sufficiently large distance is still present between anchoring areas 24 and a center of gravity of mirror plate 14.

In summary, it may thus be concluded that the connection of mirror plate 14 to mounting 10 via the four springs 20 and the four support posts 22 having anchoring areas 24 which are situated at a distance from the lateral edge of rear side 18 represents an improvement over a central mirror suspension according to the related art and a conventional mirror suspension with the aid of the springs/connecting elements which contact the lateral mirror edge. Mirror plate 14 may have a comparatively large extension a. For example, mirror plate 14 has an extension a of at least 2 mm, which may be at least 2.5 mm, in particular at least 3 mm. One particularly advantageous possible use of a mirror plate 14 of this size is discussed in greater detail below. In particular, a system formed from mirror plate 14 and the four springs 20 may have a natural frequency of at least 18 kHz, in particular at least 20 kHz, 22 kHz, 25 kHz, or 30 kHz. Mirror plate 14 may be adjusted in resonance in this way.

Each of the four anchoring areas 24 of the four support posts 22 may be situated at a distance from the at least one rotational axis 12, about a vector having a component which is oriented in parallel to mirror side 16. This contributes to an improved compensation for the moment of inertia of mirror plate 14 compared to a conventional mirror suspension having at least one anchoring area on a mirror which is intersected by the at least one rotational axis of the mirror.

In addition, the four anchoring areas 24 may be situated on rear side 18, axially symmetrically with respect to the at least one rotational axis 12. This axial symmetry of the four anchoring areas 24 with respect to the at least one rotational axis 12 may contribute to (dynamic) deformations canceling each other out. In the specific embodiment in FIG. 1a, the four anchoring areas 24 are situated axially symmetrically with respect to single rotational axis 12 and a mirror axis of symmetry 26 which is oriented orthogonally with respect to single rotational axis 12. Likewise, for adjustability of mirror plate 14 about two rotational axes 12, anchoring areas 24 may be situated on rear side 18, axially symmetrically with respect to the two rotational axes 12.

FIG. 1d shows an enlarged rear side view of mirror plate 14. A comparatively thin mirror plate 14, for example having a minimum thickness d no greater than 200 μm, in particular having a minimum thickness d of 100 μm, oriented perpendicularly with respect to mirror side 16 may be used for the micromechanical component. Braces 28 may be formed at rear side 18 to improve the stability of mirror plate 14. For example, braces 28 may extend from a central bulge 30 of mirror plate 14 to an edge area of rear side 18, the width of braces 28 decreasing with increasing distance from central bulge 30. Such a configuration of braces 28 may also be referred to as star-shaped. In addition, a lateral edge 32 may also be formed on rear side 18, into which the ends of braces 28 facing away from central bulge 30 lead. Such a configuration of rear side 18 is easily achievable by etching centrally tapering circle segments 34 into mirror plate 14.

FIG. 1e shows a cross section of the micromechanical component along a line AA′ in FIG. 1a which extends perpendicularly with respect to single rotational axis 12 and in parallel to a normal position of mirror side 16. It is apparent that the micromechanical component may be structured out of a semiconductor-on-insulator (SOI) substrate with the aid of simple etching processes. The four springs 20 may be structured out of a semiconductor substrate 36, while mirror plate 14 is producible from a semiconductor layer 38 which is situated at a distance from semiconductor substrate 36 with the aid of an insulating layer 40. Support posts 22 may be made from preceding insulating layer 40. Partial areas of all layers 36 through 40 may be used for forming mounting 10. The micromechanical component is thus manufacturable with the aid of structuring processes which may be easily carried out.

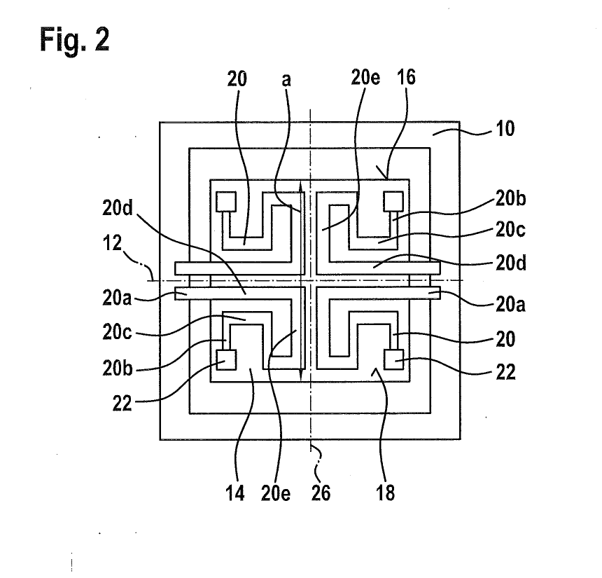

FIG. 2 shows a schematic illustration of a second specific embodiment of the micromechanical component.

In the specific embodiment in FIG. 2, the four springs 20 have a loop-shaped configuration, at least in sections. In particular, each of the four springs 20 may have a double-loop configuration, at least in sections. A looped configuration of a spring 20 may be understood to mean that two spring subsections 20c and 20d are brought close together, with an intermediate spring section 20e situated in between, by folding intermediate spring section 20e. Similarly, a double-loop spring 20 may be formed by further folding of intermediate spring section 20e. In addition, by an at least single-loop configuration of the four springs 20, these springs may be comparatively long without an increase in the dimension of the micromechanical component. This also allows a relatively stiff configuration of the four springs 20. In other respects, reference is made to the above statements with regard to the components of the micromechanical component in FIG. 2.

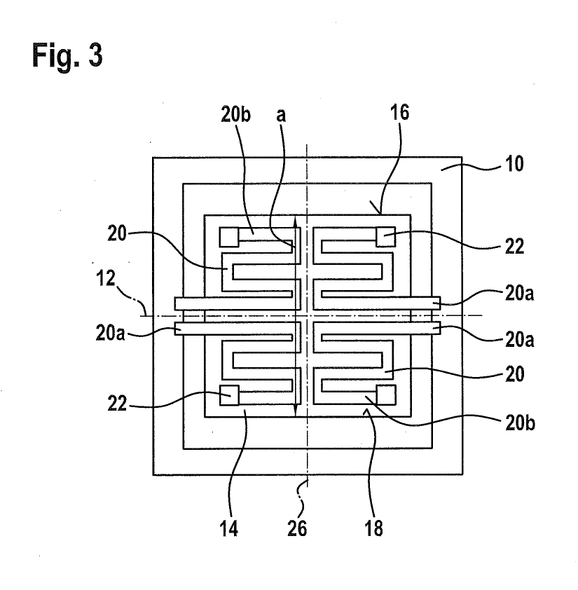

FIG. 3 shows a schematic illustration of a third specific embodiment of the micromechanical component.

The micromechanical component schematically depicted in FIG. 3 has four springs 20 which extend in a meandering shape, at least in sections. In this manner as well, the springs may advantageously be long without having to accept an undesirable enlargement of an extension of the micromechanical component. A relatively stiff configuration of the four springs 20 of the micromechanical component in FIG. 3 is thus easily achievable.

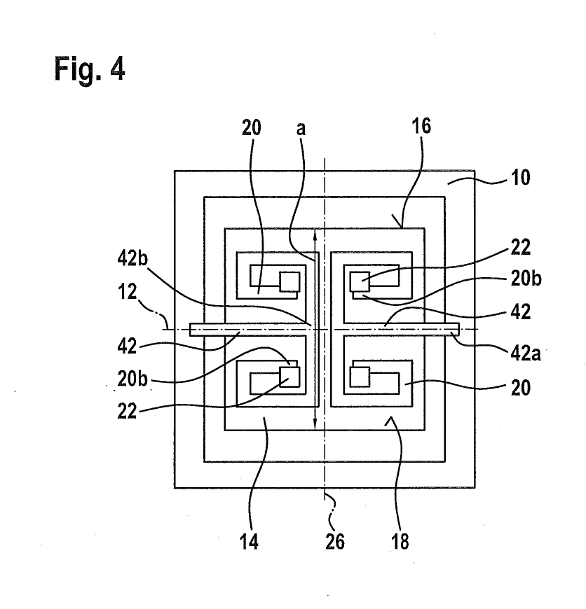

FIG. 4 shows a schematic illustration of a fourth specific embodiment of the micromechanical component.

The micromechanical component in FIG. 4 has two connecting webs 42, which at a first end 42a are anchored to a mounting frame of mounting 10 and which extend along single rotational axis 12a. A second end 42b of each connecting web 42 protrudes into the interior space bordered by the mounting frame of mounting 10. Two springs 20 each are fastened to second ends 42b of connecting webs 42. The spiral-shaped configuration of the four springs 20 is to be interpreted solely as an example. The joint connection of two springs 20 to the mounting frame of mounting 10 via a shared connecting web 42 may also be described in such a way that the spring sections of the two springs 20 which are oriented toward the mounting frame of mounting 10 lead into one another.

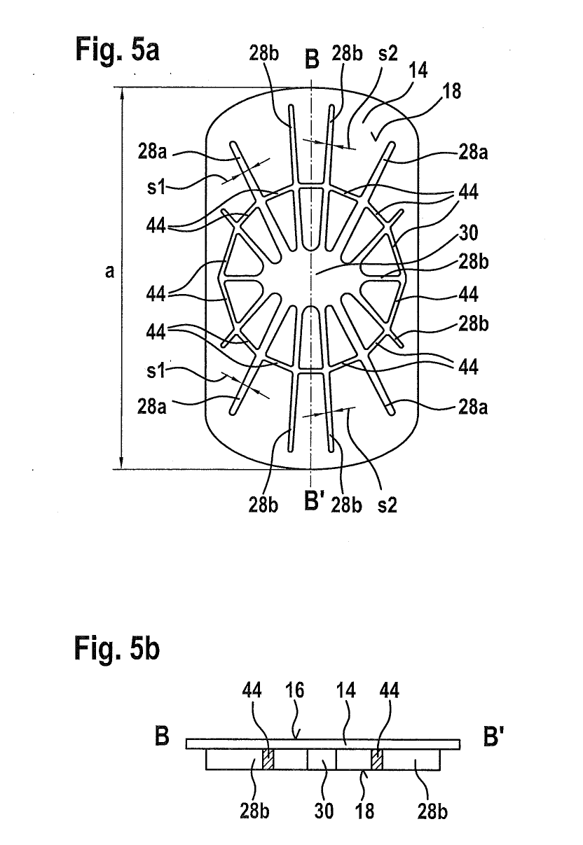

FIGS. 5a and 5b show schematic illustrations of a fifth specific embodiment of the micromechanical component, FIG. 5b illustrating a cross section along line BB′ in FIG. 5a. FIG. 5a illustrates an enlarged rear side view of mirror plate 14 of the micromechanical component. In addition, the micromechanical component may have a comparatively thin mirror plate 14. A minimum thickness d of mirror plate 14 oriented perpendicularly with respect to mirror side 16 may be less than or equal to 200 μm, in particular less than or equal to 100 μm. Once again, braces 28a and 28b are formed on rear side 18, and extend from central bulge 30 of mirror plate 14 to an edge area of rear side 18 in order to improve the stability of mirror plate 14.

Some braces 28a may extend at an angle of inclination between 30° and 60° (or at an angle of inclination between 120° and 150°) with respect to the at least one rotational axis 12. With the aid of braces 28a, deformations of corners and/or of edge areas of mirror plate 14 situated at a distance from the at least one rotational axis 12 during adjustment of the mirror plate about the at least one rotational axis 12 may thus be suppressed. In particular, braces 28a which are inclined by the angle of inclination between 30° and 60° (or by the angle of inclination between 120° and 150°) with respect to the at least one rotational axis 12 may have an (average) first width s1 which is oriented perpendicularly with respect to mirror side 16 and which is larger than an (average) second width s2 of other braces 28b perpendicular to mirror side 16. Braces 28a having the larger (average) first width s1 are thus particularly well suited for suppressing deformations of the corners and/or of the edge areas which are situated at a distance from the at least one rotational axis 12 during an adjustment of mirror plate 14 about the at least one rotational axis 12.

In addition, a ring 44 which surrounds central bulge 30 is also provided on rear side 18, the radius of the ring being smaller than a length of braces 28a and 28b extending away from central bulge 30. Despite its comparatively small minimum thickness d, ring 44 also contributes to an increase in the stability of mirror plate 14. The comparatively small radius of ring 44 also has the advantage that the moment of inertia of ring 44 is lower about single rotational axis 12.

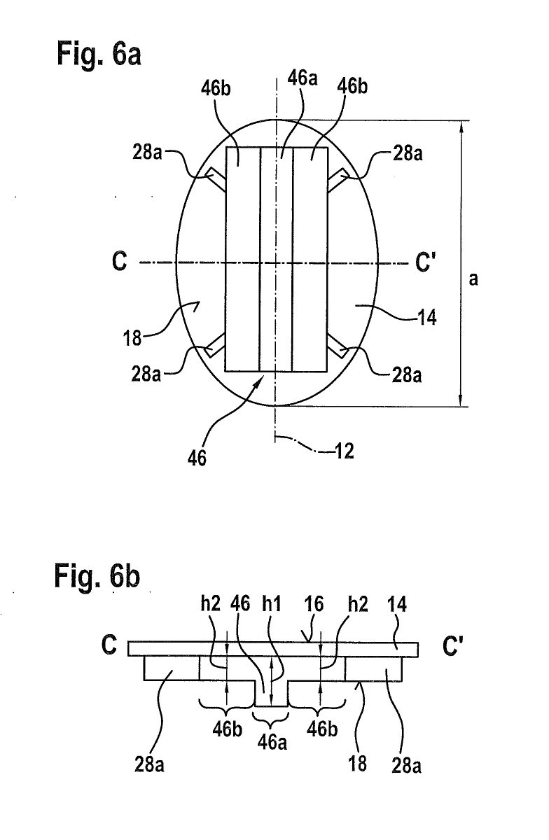

FIGS. 6a and 6b show schematic illustrations of a sixth specific embodiment of the micromechanical component, FIG. 6b illustrating a cross section along line CC′ in FIG. 6a.

FIG. 6a shows an enlarged rear side view of mirror plate 14 of the micromechanical component. In this micromechanical component as well, mirror plate 14 may be configured with a comparatively small minimum thickness d.

To ensure reliable stability of mirror plate 14, a central T bar 46 which extends along single rotational axis 12 and which has a T-shaped cross section perpendicular to single rotational axis 12 is formed on rear side 18. In other words, along single rotational axis 12, central T bar 46 has a middle portion 46a having a first height h1 which is oriented perpendicularly with respect to mirror side 16 and which is larger than a second height h2 (perpendicular to mirror side 16) of two side portions 46b of central T bar 46 on both sides of single rotational axis 12. Central T bar 46 allows a relatively low rotational inertia of mirror plate 14 with good stability in particular of a central area of mirror plate 14.

Additional braces 28a may optionally be formed on rear side 18 of mirror plate 14. In particular due to equipping rear side 18 of mirror plate 14 with braces 28a which are inclined by an angle of inclination between 30° and 60° (or by an angle of inclination between 120° and 150°) with respect to the at least one rotational axis 12, deformations of corners and/or of edge areas of mirror plate 14 which are situated at a distance from the at least one rotational axis 12 during adjustment of the mirror plate about the at least one rotational axis 12 may be suppressed in a targeted manner.

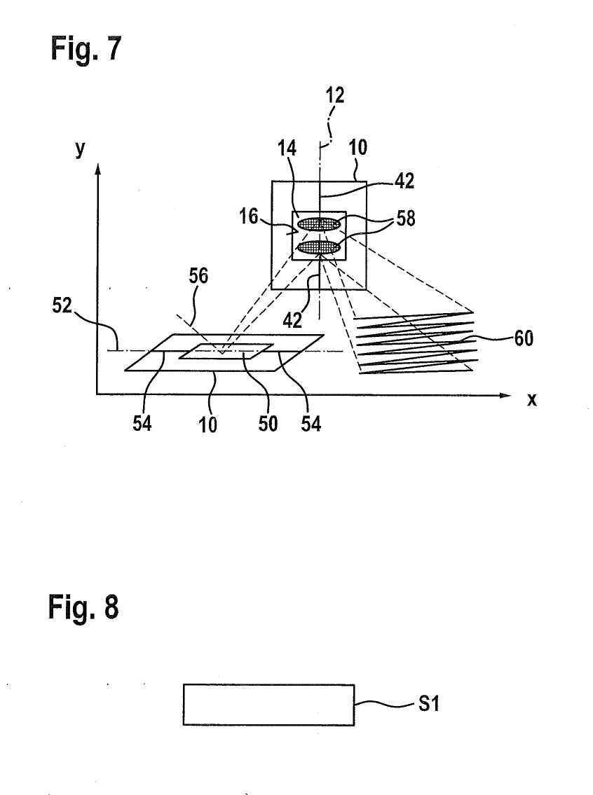

FIG. 7 shows a schematic illustration of a seventh specific embodiment of the micromechanical component.

The micromechanical component schematically illustrated in FIG. 7 may be a refinement of the specific embodiments described above. In addition to mirror plate 14 which is adjustable about rotational axis 12, the micromechanical component in FIG. 7 has an additional micromirror 50. Micromirror 50 is adjustable in relation to mounting 10 about a rotational axis 52 which is oriented perpendicularly with respect to (single) rotational axis 12 about which mirror plate 14 is adjustable relative to mounting 10. For this purpose, micromirror 50 may also be connected to mounting 10 via at least two springs 54. Micromirror 50 is situated with respect to mirror plate 14 in such a way that a light beam 56 which is deflected on micromirror 50 is deflectable onto mirror side 16 of mirror plate 14.

As stated above, advantageous mirror plate 14 may have a comparatively large configuration, which at the same time still ensures good adjustability of mirror plate 14 about rotational axis 12. (Mirror plate 14 may have dimensions of approximately 1.8 mm×2.3 mm.) Mirror plate 14 is therefore well suited for a dual-mirror system, light beam 56 being deflected on mirror plate 14 in a first spatial direction y with the aid of micromirror 50. Due to advantageously large mirror side 16 of mirror plate 14, even when micromirror 50 is adjusted about rotational axis 52 for a relatively large adjustment angle it is still ensured that light beam 56 which is reflected on micromirror 50 strikes mirror side 16 of mirror plate 14. (This is schematically illustrated by the two light incidence points 58 in FIG. 7.) Light beam 56 may subsequently also be deflected in a second spatial direction x with the aid of mirror plate 14. Mirror plate 14 is thus advantageously placeable as a second mirror in a beam path of a dual-mirror system.

In one specific embodiment, micromirror 50 is adjustable quasi-statically about rotational axis 52. In contrast, a resonant oscillation of mirror plate 14 about (single) rotational axis 12 may be used. For example, for this purpose mirror plate 14 may be set in oscillation at a frequency between 10 kHz and 50 kHz. A natural frequency of the oscillation system which may be implemented from mirror plate 14 and the four springs 20 may be fixed due to the many degrees of freedom of configuration in forming mirror plate 14 and the four springs 20.

Due to the connection of the four springs 20 via the four support posts 22 to rear side 18 of mirror plate 14, it is ensured that, even during resonant oscillation of mirror plate 14 about rotational axis 12, hardly any deformations occur at mirror side 16. In particular, as a result of the advantageous connection of mirror plate 14 via the four springs 20, the surface deformation which is relevant for the light incidence point of light beam 56 is 0.2 μm maximum. An undesirable expansion of light beam 56 which is reflected on mirror side 16 is thus prevented. This ensures good resolution of an image which is generated on an image area 60 with the aid of mirrors 14 and 50 via the deflection of light beam 56, for example a laser beam.

Due to the advantageous usability of the micromechanical component for projecting images, a micromirror device having this type of micromechanical component is advantageously usable as an image projector and/or film projector.

FIG. 8 shows a flow chart for explaining one specific embodiment of the manufacturing method for a micromechanical component.

The manufacturing method described in greater detail below with reference to the flow chart in FIG. 8 may be carried out, for example, for manufacturing the micromechanical components described above. However, it is pointed out that other micromechanical components are also manufacturable with the aid of the manufacturing method in FIG. 8.

When the manufacturing method is carried out, a mirror plate at a mirror side and a rear side which faces away from the mirror side is connected at least via four springs to a mounting in a method step S1. This takes place in such a way that during operation of the finished micromechanical component, the mirror plate is adjusted with respect to the mounting about at least one rotational axis. For this purpose, each of the four springs is partially guided along the rear side of the mirror plate, and each of the four springs is connected to the mirror plate via one support post each which in each case contacts an anchoring area situated on the rear side.

Carrying out the manufacturing method also achieves the above-mentioned advantages, which are not described again at this point.

1-15. (canceled)

16. A micromechanical component, comprising:
a mounting; and
a mirror plate which is adjustable with respect to the mounting about at least one rotational axis and which has a mirror side and a rear side which faces away from the mirror side, the mirror plate being connected to the mounting at least via four springs;
wherein each of the four springs extends partially along the rear side of the mirror plate and is connected to the mirror plate via one support post each, which in each case contacts an anchoring area situated on the rear side.

17. The micromechanical component of claim 16, wherein each of the four anchoring areas of the four support posts is situated at a distance from the at least one rotational axis, about a vector having a component which is oriented in parallel to the mirror side.

18. The micromechanical component of claim 16, wherein the four anchoring areas are situated on the rear side, axially symmetrically with respect to the at least one rotational axis.

19. The micromechanical component of claim 18, wherein the four anchoring areas are situated on the rear side, axially symmetrically with respect to the single rotational axis and a mirror axis of symmetry which is oriented orthogonally with respect to the single rotational axis, or axially symmetrically with respect to the two rotational axes.

20. The micromechanical component of claim 16, wherein each of the four anchoring areas of the four support posts is situated at a distance from a lateral edge of the rear side.

21. The micromechanical component of claim 16, wherein the mirror plate has an extension of at least 2 mm, and a system formed from the mirror plate and the four springs has a natural frequency of at least 18 kHz.

22. The micromechanical component as recited in claim 16, wherein the four springs have a spiral-shaped, meander-shaped, and/or loop-shaped configuration, at least in sections

23. The micromechanical component of claim 16, wherein braces which extend from a central bulge of the mirror plate to an edge area of the rear side are formed on the rear side of the mirror plate.

24. The micromechanical component of claim 23, wherein some of the braces are inclined by an angle of inclination between 30° and 60° with respect to the at least one rotational axis, and have a first width, oriented perpendicularly with respect to the mirror side, which is larger than a second width of the other braces which is oriented perpendicularly with respect to the mirror side.

25. The micromechanical component of claim 23, wherein a ring which surrounds the central bulge, and whose radius is smaller than a length of the braces extending away from the central bulge, is formed on the rear side.

26. The micromechanical component of claim 16, wherein a central T-bar which extends along the single rotational axis and which has a T-shaped cross section perpendicular to the single rotational axis is formed on the rear side of the mirror plate.

27. The micromechanical component of claim 16, further comprising:
a micromirror which is adjustable in relation to the mounting about a rotational axis which is oriented perpendicularly with respect to the single rotational axis about which the mirror plate is adjustable with respect to the mounting, the micromirror being situated in relation to the mirror plate so that a light beam which is deflected on the micromirror is deflectable onto the mirror side of the mirror plate.

28. A micromirror device, comprising:
a micromechanical component, including:
a mounting; and
a mirror plate which is adjustable with respect to the mounting about at least one rotational axis and which has a mirror side and a rear side which faces away from the mirror side, the mirror plate being connected to the mounting at least via four springs;
wherein each of the four springs extends partially along the rear side of the mirror plate and is connected to the mirror plate via one support post each, which in each case contacts an anchoring area situated on the rear side.

29. The micromirror device of claim 28, wherein the micromirror device is configured as at least one of an image projector and a film projector.

30. A manufacturing method for a micromechanical component, the method comprising:
connecting a mirror plate including a mirror side and a rear side which faces away from the mirror side to a mounting at least via four springs so that during operation of the finished micromechanical component, the mirror plate is adjusted with respect to the mounting about at least one rotational axis; and
guiding each of the four springs partially along the rear side of the mirror plate, and connecting each of the four springs via one support post each, which in each case contacts an anchoring area situated on the rear side, to the mirror plate.
